(19) United States
(12) Patent Application Publication
(10) Pub. No.: US 2008/0024188 A1
(43) Pub. Date: Jan. 31, 2008

(54) Junction field effect transistor level shifting circuit

(76) Inventors: Richard K. Chou, Palo Alto, CA (US); Damodar R. Thummalapally, Milpitas, CA (US)

Correspondence Address: WALKER & SAKO, LLP, Suite 235, 300 South First Street, San Jose, CA, 95113, US

(21) Appl. No.: 11/495,099

(22) Filed: Jul. 28, 2006

(51) Int. Cl. H03L 5/00

(52) U.S. Cl. 327/333

(57) ABSTRACT

A level shifting circuit can include a first driver junction field effect transistor (JFET) of a first conductivity type having a source coupled to a first supply node, a drain coupled to an output node, and a gate coupled to a first driver control node. A first driver control circuit can include a first control JFET of a second conductivity type having a source coupled to a second supply node, a gate coupled to an input node that is coupled to receive an input signal, and a first level shifting stack coupled between the source of the first control JFET and the first driver control node. The magnitude of the potential between the first supply node and the second supply node is greater than a voltage swing of the input signal.

This application claims the benefit of U.S. patent application Ser. No. 11/452,442 filed on Jun. 13, 2006, which claims the benefit of U.S. Provisional Patent Application Ser. No. 60/799,787 filed on May 11, 2006. The contents of both of these applications are incorporated by reference herein.

### TECHNICAL FIELD

The present invention relates generally to level shifting circuits, and more particularly to level shifting circuits that include junction field effect transistors (JFETs).

### BACKGROUND OF THE INVENTION

Level shifting circuits can translate an input signal that varies within one voltage range, to an output signal that varies within another, different voltage range. Typically, level shifting circuits can be utilized to translate between logic signals operating at different signal voltage levels (e.g., TTL to CMOS). Level shifting circuits for metal-oxide-semiconductor (MOS) type technologies, particularly CMOS type technology are well known.

Co-pending U.S. patent application Ser. No. 11/452,442 filed on Jun. 13, 2006 and U.S. Provisional Patent Application Ser. No. 60/799,787 filed on May 11, 2006, both by Ashok K. Kapoor, show examples of novel circuits that include junction field effect transistors (JFETs) that operate at relatively low voltage levels (e.g., 0 to +0.5 volts). Such circuits can form integrated circuits that include few, or preferably no MOS type transistors. Accordingly, CMOS type level shifting circuits are of no benefit in shifting a low voltage internal signal (e.g., 0 to +0.5 volts) to some higher output signal level (e.g., +1.0 volts or higher).

### BRIEF DESCRIPTION OF THE DRAWINGS

FIG. 1 is a block schematic diagram of a level shifting circuit according to a first embodiment.

FIG. 2 is a block schematic diagram of an integrated circuit according to another embodiment.

FIG. 3 is a schematic diagram of a level shifting circuit according to a third embodiment.

FIG. 4A is a schematic diagram of a delay circuit that can be included in the embodiment of FIG. 3. FIG. 4B is a block schematic diagram of another level shifting circuit according to another embodiment.

FIG. 5 is a timing diagram showing the operation of the embodiment of FIG. 3.

FIG. 6 is a timing diagram showing the operation of the embodiment of FIG. 3 and variations thereof, at various boosted voltage levels.

FIG. 7 is a boosted voltage generator stage according to an embodiment.

FIG. 8 is a block schematic diagram of a positive voltage generator according to an embodiment.

FIG. 9 is a diagram showing the operation of the circuit of FIG. 8 and variations thereof.

### DETAILED DESCRIPTION OF THE EMBODIMENTS

Various embodiments of the present invention will now be described in detail with reference to a number of drawings. The embodiments show level shifting circuits and methods constructed with junction field effect transistors (JFETs), for example four terminal JFETs of complementary conductivity types (n-channel and p-channel types). Four terminal JFETs can include two control terminals on different sides of a channel region.

The disclosed embodiments are in contrast to conventional level shifting circuits formed from complementary metal-oxide-semiconductor (CMOS) type technologies, constructed with MOS type transistors.

Referring now to FIG. 1, a level shifting circuit according to a first embodiment is shown in block schematic diagram, and designated by the general reference character 100. A level shifting circuit 100 can receive an input signal INB having a first voltage swing, and generate an output signal OUTH having a second voltage swing, greater than the first voltage level.

In the particular example of FIG. 1, input signal INB and output signal OUTH can have an inverse relationship with one another. That is, when input signal INB transitions from low-to-high, output signal OUTH can transition from high-to-low, and vice versa. In addition, in the example shown, input signal INB can swing between a low power supply voltage VSS, and a high power supply voltage VDDL. At the same time, output signal OUTH can swing between the low power supply voltage VSS and a boosted high power supply voltage VDDH that is greater than power supply voltage VDDL.

In the embodiment of FIG. 1, level shifting circuit 100 can include a first control section 102, a second control section 104, a driver section 106, and a low voltage control section 108. A first control section 102 can control the activation of a driver control signal PUPB at a first node 114. More particularly, first control section 102 can pull first node 114 low in response to an input signal INB being low. In the particular example of FIG. 1, a first control section 102 can include a first control n-channel JFET (NJFET) N11, a first bias stack circuit 116, and a first disable p-channel JFET (PJFET) P12. Transistor N11 can have a source connected a low power supply node 112 and a first gate coupled to an inverting output of low voltage control circuit 108. Transistor P12 can have a source connected to boosted power supply node 110, a gate connected to a disable node 118, and a drain connected to a first driver control node 114. A bias stack circuit 116 can be connected between first driver control node 114 and a drain of transistor N11.

A first bias stack circuit 116 can prevent the potential between first driver control node 114 and a drain of transistor N11 from falling below a predetermined voltage. This can enable first driver control node 114 to be driven at boosted voltage levels. In the particular example shown, when transistor N11 is enabled (has a low impedance), first bias stack circuit 116 can maintain first driver control node 114 above a source-gate forward bias voltage (e.g., about 0.6 to 0.7 volts) with respect to boosted high voltage level VDDH, that is under about 0.6 volts with respect to VDDH.

A second control section 104 can control the de-activation of a driver control signal PUPB at first driver control node 114. Second control section 104 can pull a disable node 118 low in response to an input signal INB being high. This, in turn, can result in transistor P11 being turned on, and driving signal PUPB high. In the particular example of FIG. 1, a second control section 104 can include a second control NJFET N12, a second bias stack circuit 120, and a second disable PJFET P12. Transistor N12 can have a source connected a low power supply node 112 and a first gate coupled to an input node 122. Transistor P12 can have a source connected to boosted power supply node 110, a gate connected to first driver control node 114, and a drain connected to a disable node 118. A second bias stack circuit 120 can be connected between disable node 118 and a drain of transistor N12. A second bias stack circuit 120 can operate in the same manner as first bias stack circuit 116, preventing the potential between disable node 118 and a drain of transistor N12 from falling below a predetermined voltage.

Transistors P12 and P11 can be arranged in a cross-coupled manner, with the gate of one being connected to the drain of the other. In this arrangement, when a first driving signal PUPB is active (low in this example), transistor P12 can be turned on, pulling disable control node 118 high, which turns off transistor P11, preventing current from flowing through control section 102. Transistor P12 can be turned off, preventing current from flowing through first control section 102. Conversely, when a disable node 118 is driven low, transistor P11 can be turned on, pulling first driver control node 114 high.

In this way, control sections (102 and 104) can operate according to low voltage signals (IN and IN′) to drive control nodes 114 and 118 at higher boosted voltage levels. In addition, current can be conserved by preventing current from flowing through control sections (102 and 104) regardless of output driver state (i.e., driving to a boosted high or low).

Referring still to FIG. 1, a low voltage control section 108 can receive input signal INB, and in response, generate output signal IN′, which can be the inverse of signal INB, and signal PDN, which can follow input signal INB. Low voltage control section 108 can operate between a non-boosted high power supply voltage VDDL and a low voltage power supply VSS.

In this way, one driving operation (in this case a pull-down operation), can operate according to low voltage logic signals, and not include boosted voltage signals, or circuits.

A driver section 106 can drive an output node 124 between a boosted high supply level VDDH and a low power supply voltage VSS. In the arrangement shown, when first driving control signal PUPB is a predetermined potential less than a boosted high supply voltage VDDH, output node 124 can be driven to a boosted high supply voltage VDDH. When first driving control signal PUPB is not a predetermined potential less than a boosted high supply voltage VDDH, a driver section 106 can create a high impedance path between output node 124 and boosted high supply node 110. In this way pull-up operations to a boosted high voltage level can be controlled.

When second driving control signal PDN is a predetermined potential above a low supply voltage VSS, output node 124 can be driven to a low supply voltage VSS. However, when second driving control signal PDN is not a predetermined potential above low supply voltage VSS, a driver section 106 can create a high impedance between output node 124 and low supply node 112. In this way pull-down operations to a low voltage level can be controlled.

It is noted that in the example of FIG. 1, NJFETs (N11/N12) and PJFETs (P12/P11) are four terminal JFET devices, each having a front gate, back gate, source, and drain. In the example of FIG. 1, PJFET P12 has a front gate connected to first driver control node 114, and a back gate connected to a boosted high power supply node 110. A PJFET P22 can have a front gate connected to disable control node 118, and a back gate connected to a boosted high power supply node 110. In addition, each NFET and PFET can be an “enhancement” mode JFETs, as described in U.S. patent application Ser. No. 11/452,442 and U.S. Provisional Patent Application Serial No. 60/799,787, referred to and incorporated by reference above.

In addition, low voltage control circuit 108 is preferably formed from JFET devices, preferably, four terminal NJFET and PJFET enhancement mode devices.

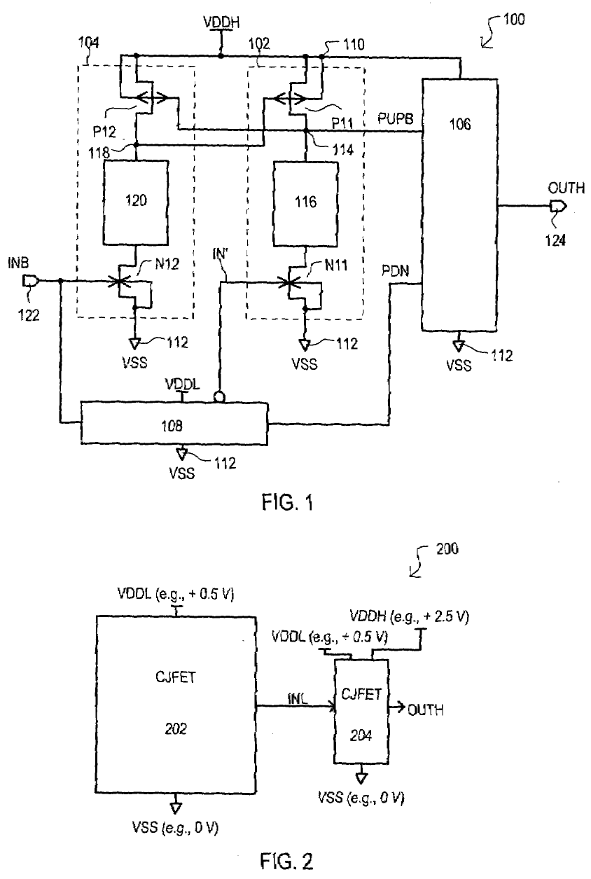

Referring now to FIG. 2, one example of a semiconductor device, according to one embodiment is shown in a block diagram and designated by the general reference character 200. A semiconductor device 200 can include a low voltage core section 202 and one or more level shifting sections 204. A core section 202 can operate at a relatively low voltage, in this case between 0 and +0.5 volts. Preferably, a core section 202 is formed from JFET devices, preferably complementary JFET devices (CJFETs), even more preferably four terminal complementary JFET devices.

A level shifting section 204 can have the general form of the circuit of FIG. 1 or subsequently described embodiments, providing a shift in voltage levels between a low voltage range of 0 to +0.5 volts, to a boosted voltage level of 0 to about +2.5 volts. However, as will be described below, higher voltage levels can be accommodated.

In this way, a circuit having JFET devices operating at a power supply level of about +0.5 volts can generate output signals compatible with other logic types, such as complementary metal-oxide-semiconductor (CMOS) logic, as but one example. More particularly, a circuit having JFET devices operating at about +0.5 volts and generate output signals with swings greater than 0.5 volts.

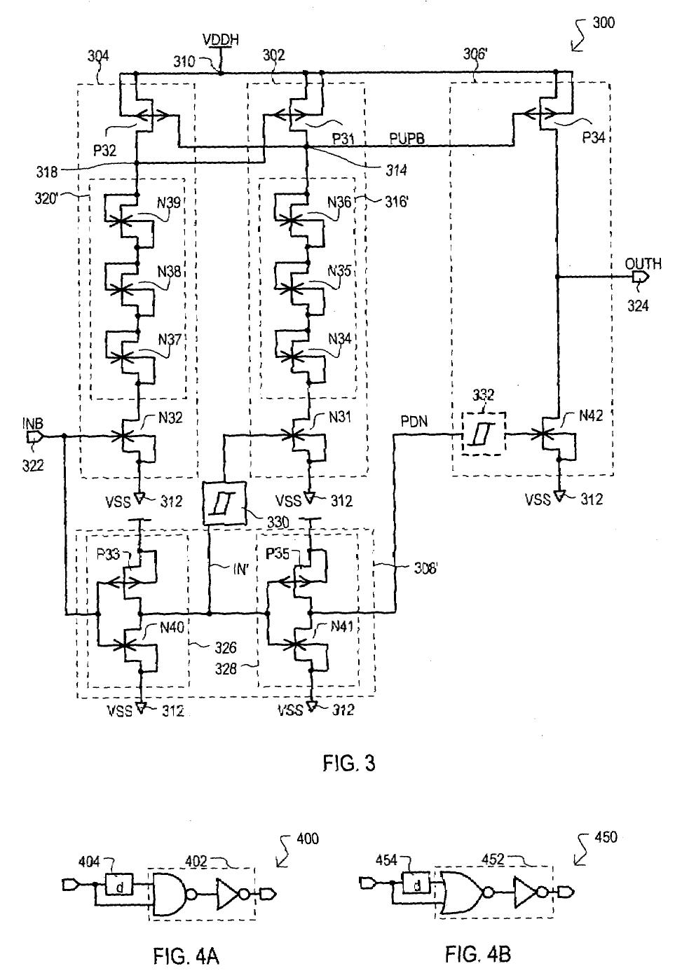

Referring now to FIG. 3, a level shifting circuit according to another embodiment is shown in a schematic diagram and designated by the general reference character 300. A level shifting circuit 300 can include some of the same general sections as FIG. 1, thus like sections are referred to by the same reference character, but with the first digit being a “3” instead of a “1”.

The example of FIG. 3 shows a level shifting circuit that can be formed from four terminal JFET devices of complementary conductivity type (n-channel and p-channel). Thus, within first control section 302, a first bias stack 316′ can each include a number of NJFETs (N34 to N36) arranged in series with one another. In the particular example shown, each NJFET can have a first gate connected to its drain and a second gate connected to its source. In such an arrangement, each such NJFET can introduce about a 0.6 to 0.7 volt drop between a source of transistor N21 and first driver control node 314. As a result, first bias stack 316′ can ensure a 1.5 volt difference is maintained between such nodes. Of course, FIG. 3 shows an arrangement that includes three JFETs in a bias stack. For higher voltage levels, more JFETs could be included, and for lower voltage levels, fewer JFETs could be included.

Second bias stack 320′ can have the same general structure as first bias stack 316′, including NJFETs N37 to N39 arranged in series with one another.

In alternate embodiments, all or a portion of first and/or second bias stacks (316′ and 320′) can be replaced by diodes to introduce predetermined voltage drops through such stacks.

In this way, a level shifter can include one or more control sections (e.g., 302 and/or 304) that include stacks of JFET devices arranged in series to ensure minimum voltage levels at control nodes (e.g., 314 and/or 318). Such minimum voltage levels can enable control signals at boosted voltage levels that do not forward bias JFETs connected to the boosted voltage supply.

A low voltage control section 308′ can include logic circuits formed from only JFET devices, preferably only four terminal JFET devices. For example, a low voltage control section 308′ can include a first inverting logic circuit 326 and a second inverting logic circuit 328 arranged in series with one another. A first logic circuit 326 can have an input connected to input node 322 and an output connected a gate of transistor N31. A second logic circuit 328 can have an input connected to an output of first logic circuit 326, and an output that provides second driver control signal PDN. In the very particular example shown, first and second logic sections (326 and 328) are inverters, formed with complementary enhancement mode JFET pairs, P33/N40 and P35/N41, respectively.

Referring still to FIG. 3, in the example shown, a driver section 306′ can be formed from only JFET devices, preferably only four terminal JFET devices. Thus, driver circuit 306′ can include a pull-up PJFET P34 and a pull-down NJFET N42. Transistor P34 can have a source and back gate connected to a boosted high power supply node 310, a front gate connected to first driver control node 314, and a drain connected to output node 324. Transistor N42 can have a source and back gate connected to a low power supply node 312, a front gate connected to receive second driver control signal PDN, and a drain connected to output node 324. As understood from the above discussion, due to operation of bias stack, a potential at the gate of transistor P34 can be maintained at a level sufficient to prevent forward biasing of p-n junctions within transistor P34. Thus, transistor P34 can be controlled by boosted signal levels, while transistor N42 can be controlled by a low voltage signal.

It is noted that transistor P31 and P32 can be “weak” transistors as compared to transistors within their pull-down paths (between respective drains and low power supply node 312). For example, a width-to-length (W/L) ratio of such transistors can be considerably smaller than NJFETs in of the pull-down path.

It is also noted that while a level shifter circuit 300 of FIG. 3 preferably operates to prevent a forward biasing of p-n junctions within transistors P31, P32 and P34, such devices can have an inherent robustness. In the event of such a forward biasing case, such p-n junctions will clamp a potential difference to such a p-n junction forward bias drop.

Referring still to FIG. 3, a level shifting circuit 300 can optionally include a delay circuit 330 or 332. Such a delay circuit can compensate for inherent differences in signal propagation time of the circuit in response to one type of transition (low-to-high) of signal INB, versus another type of transition (high-to-low), that could otherwise result in both driver devices P34 and N42 being turned on at the same time, and thus draw a large amounts of current. Said in another way, delay circuits 330 or 332 can ensure driver device N42 is turned off before transistor P34 is turned on, or vice versa.

In the particular example of FIG. 3, it is assumed that the propagation of an input signal (INB) value signal through low voltage control circuit 308′ can take longer than the activation of a signal via control sections 302 and 304. Thus, it is desirable to delay a high-to-low transition at first control node 314. Accordingly, a delay circuit 330 can be situated between low voltage control section 208′ and a gate of transistor N31. Delay circuit 330 can introduce more delay into a high-to-low transition than a low-to-high transition. This can delay the activation of transistor P34 until after transistor N42 is fully turned off.

However, in the event an input signal (INB) value signal through low voltage control circuit 308′ takes less time than the activation of a signal via control sections 302 and 304, it would be desirable to delay a low-to-high transition in second driver control signal PDN. In such a case, a delay circuit 332 could be included between the output of low voltage control circuit 308′ and gate of transistor N42. Such a delay circuit can introduce more delay into a low-to-high transition than a high-to-low transition.

Referring to FIG. 4A, one example of a delay circuit is shown in a schematic diagram and designated by the general reference character 400. Such a circuit can include an AND gate 402 having a delay element 404 connected to one input. Such a configuration can introduce a delay into a low-to-high transition of an input signal. Of course, FIG. 4A is but one of the many possible delay circuits than could be used to delay one particular type of signal transition.

Depending upon where a particular delay circuit is included within a level shifting circuit, a different type of transition may have to be delayed (i.e., high-to-low). In such an embodiment, a delay circuit like that of FIG. 4B can be used. Such a delay circuit 450 can include an OR gate 452 having a delay element 454 coupled to one input. Again, FIG. 4B is but one of the many possible delay circuits than could be used to delay one particular type of signal transition.

Referring back to FIG. 3, the particular location of a delay circuits 330 or 332 are but one example of how signal delays can be introduced into signal transitions. Other embodiments can include different circuit locations.

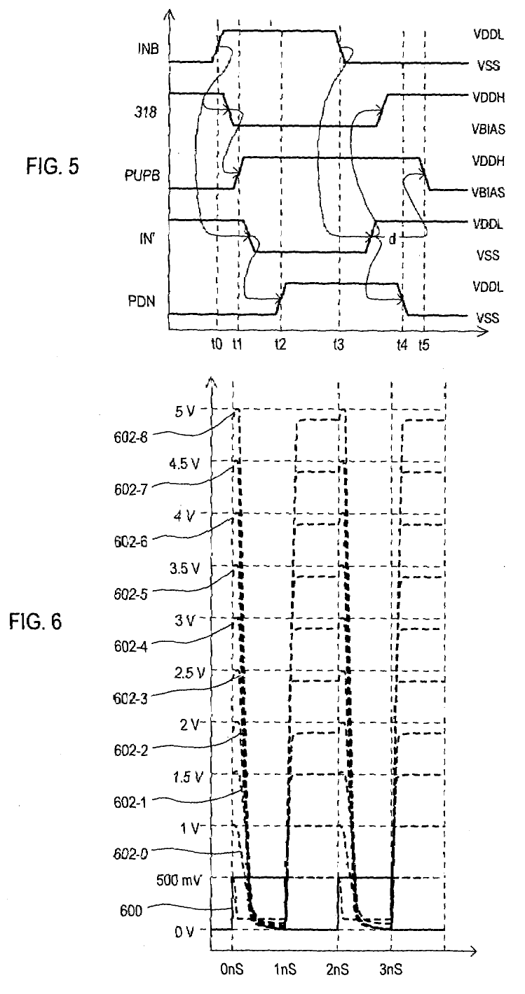

Having described one particular arrangement of a level shifting circuit in FIG. 3, the operation of the circuit will now be described with reference to FIG. 5. FIG. 5 is a timing diagram showing the response of input signal INB, a disable node 318, a first driver control signal PUPB, signal IN′ output from low voltage control section 308′, and a second driver control signal PDN.

Referring now to FIG. 3 in conjunction with FIG. 5, prior to time t0, an input signal INB can be low. As a result, within first control section 302, transistor N31 can be turned on, and first driver control node 314 can be pulled low enough to turn on driver transistor P34 (e.g., about VDDH—˜0.6 volts). At the same time, within second control section 304, transistor N32 can be turned off, thus preventing a current path through such a circuit. Disable transistor P32 can be turned on, pulling node 318 to about VDDH. In addition, the low INB signal can be applied as a low signal PDN to a gate of driver transistor N42, turning the transistor off. As a result, output node 324 can be at a boosted high voltage level due to the operation of driver transistor P34, and isolated from a low supply voltage VSS by transistor N42.

At about time t0, input signal INB can transition from a low logic level (VSS) to a high logic level (VDDL). As a result, within second control section 304, disable node 318 can be pulled lower (e.g., about VDDH—˜0.6 volts), which can turn on transistor P31. This can pull first driver control node 314 high, which can turn off transistors P32 and P34, isolating output node 324 from a boosted supply voltage node 310, and preventing current flow through second control section. In addition, by operation of inverting logic 326 signal IN′ can go low. Within first control section 302, transistor N31 can be turned off, enabling transistor P31 (which can be a weaker device) to pull-up first driver control node 314. Still further, a signal IN′ can be inverted by inverting logic 328 to drive second driver control signal PDN high. As a result, driver transistor N42 can be turned on, pulling output node 324 down to the lower power supply level VSS.

As previously noted, in the particular example of FIG. 3 it is assumed that signal propagation through first and second control sections (302 and 304) can be faster than through low voltage control section 308′. Consequently, driver control signal PUPB can transition high at time t1, sooner than driver control signal PDN transitions high at time t2.

At about time t3, input signal INB can return to a low logic level (VSS). Within second control section 304, transistor N32 can be turned off. By operation of low voltage control section 308′, signal IN′ can be driven high, and second driver control signal PDN can be driven low at time t4. However, to ensure that transistors P34 and N42 are not turned on at the same time, delay circuit 330 can delay a low-to-high transition in signal IN′, to ensure that transistor P34 is only turned on at a time t5, occurring after transistor N42 is turned off.

In this way, level shifter circuit can be formed that includes only JFET devices. More particularly, a level shifter circuit can be formed with four terminal enhancement mode JFET devices of both n-channel and p-channel conductivities.

Referring now to FIG. 6, a timing diagram shows the operation of variations on a circuit like that of FIG. 3. FIG. 6 shows an input signal 600, such as INB of FIG. 3. Also included are various possible output signals 602-0 to 602-8 corresponding to different boosted voltage levels. Such different boost levels can be achieved by increasing the number of devices within bias stacks 316′ and 320′ as needed to ensure a sufficiently high voltage can be maintained at nodes 314 and 318. More particularly, each NJFET device within each bias stack (e.g., 316′ and 320′) can provide a minimum voltage bias of about 0.6 to 0.7 volts. Thus, waveform 602-3 can correspond to circuit 300 of FIG. 3, having three devices within each bias stack (316′ and 320′).

In this way, increasingly higher boosted voltage levels can be accommodated by increasing the number of devices within bias stacks.

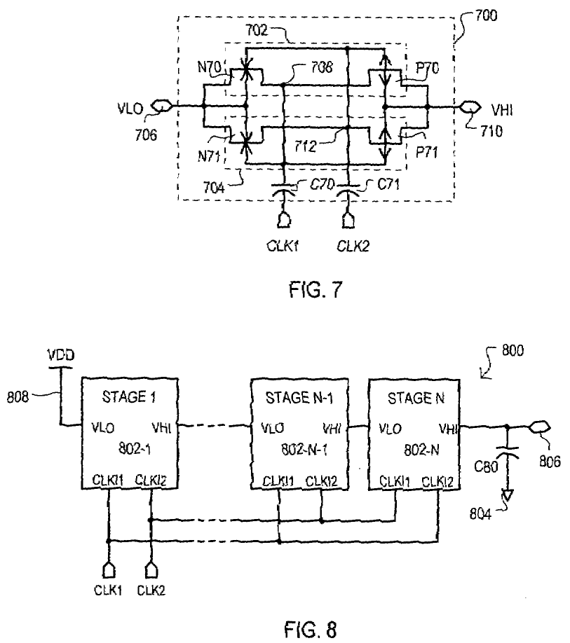

Referring now to FIG. 7, an example of a boosted voltage generator stage according to an embodiment is shown in a schematic diagram and designated by the general reference character 700. A boosted generator stage 700 can be used to generate a boosted voltage, like VDDH shown in the above embodiments. The particular boosted voltage stage 700 can include a first stage 702, a second stage 704, and capacitors C70 and C71. First stage 702 can include an n-channel JFET N70 having a source-drain path connected between a low boost node 706 and a first charge node 708, and a p-channel JFET P70 having a source-drain path connected between first charge node 708 and a high reference node 710. Gates of JFETs P70 and N70 can be connected to second charge node 712.

A second stage 704 can include an n-channel JFET N71 having a source-drain path connected between low boost node 706 and a second charge node 712, and a p-channel JFET P71 having a source-drain path connected between second charge node 712 and a high reference node 710. Gates of JFETs P71 and N71 can be connected to first charge node 708. Capacitor C70 can have one terminal connected to first charge node 708 and another terminal that receives a periodic clock signal CLK1. Capacitor C71 can have one terminal connected to second charge node 712 and another terminal that receives a periodic clock signal CLK2, which can be essentially the inverse of clock signal CLK1.

In operation, when signal CLK1 is low and signal CLK2 is high, previously charged capacitor C71 can drive second charge node 712 above the potential at low reference node 706. JFET P71 can be turned on and JFET N71 can be turned off, thus driving high boost node 710 to a potential higher than high reference node 710. At the same time, JFET N70 can be turned on and JFET P70 can be turned off, connecting first charge node 708 to low reference node 706. Signal CLK1 can charge capacitor C70 to a potential lower than low reference node 706.

When signal CLK1 is high and signal CLK2 is low, previously charged capacitor C70 can drive first charge node 708 above the potential at high reference node 710. JFET P70 can be turned on, and JFET N70 can be turned off, thus driving high boost node 710 to a higher potential than high reference node 710. At the same time, JFET P71 can be turned off and JFET N71 can be turned on, connecting second charge node 712 to low reference node 706. Signal CLK2 can charge capacitor C71 to a potential lower than low reference node 706.

In the example of FIG. 7, all JFETs can be four terminal JFETs, having a first control gate and second control gate separated from one another by a channel region. First gate connections for such transistors have been described above. In addition, second gates of JFETs N70 and N71 can be commonly connected to low boost node 706, while second gates of JFETs P70 and P71 can be commonly connected to a high reference node 710.

In this way, a boosted voltage generator stage can generate a boost voltage utilizing JFETs, preferably complementary four terminal JFETs.

While a single boosted voltage generator stage, like that of FIG. 7, can provide a given boosted voltage. It may be desirable to provide boosted voltages of even greater magnitude. In such a case, several generator stages like that of FIG. 7 can be connected in series to form a voltage generator circuit. One example of such an arrangement is shown in FIG. 8.

FIG. 8 shows a voltage generator 800 that can include a number of generator stages 802-1 to 802-N, each of which can take the form of generator stage 700 shown in FIG. 7. A last generator stage 802-N can have a low boost node connected to a boosted supply node 806. A capacitor C80 can be connected between boosted supply node 806 and a reference supply node 804. A next to last generator stage 802-N-1 can have a high boost node (VHI) connected to a low reference node (VLO) of next stage (i.e., 802-N). Each generator stage can be connected to the next stage in this fashion, ending with a first generator stage 802-1, which can have a low reference node VLO connected to a high supply node 808. Clock signals CLK1 and CLK2 can be connected to generator stages (802-1 to 802-N) in an alternating fashion with respect to a first clock inputs CLKI1 and a second clock inputs CLKI2.

In this way, a series of generator stages can be connected together to generate boosted voltage levels of greater magnitude.

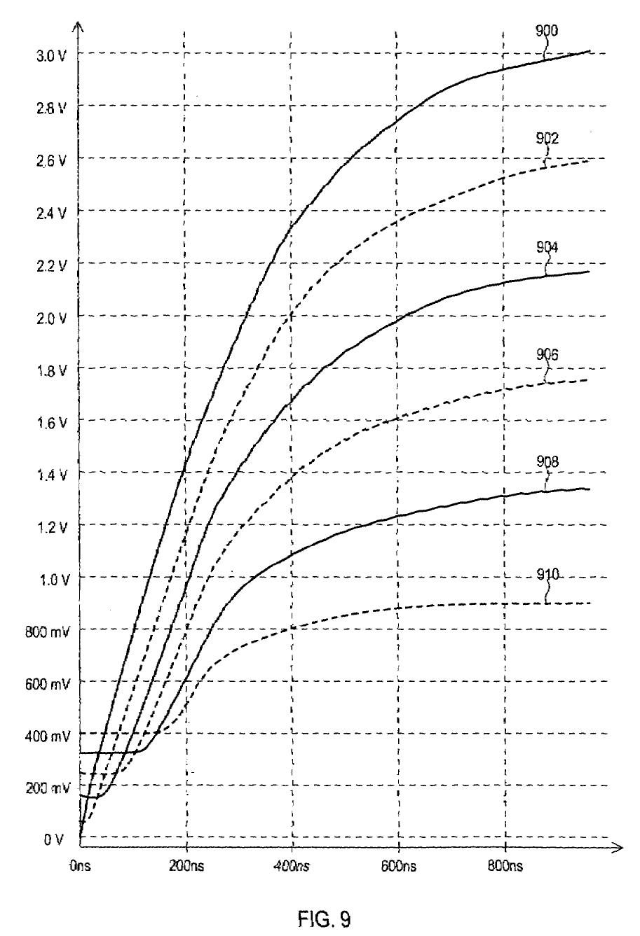

Referring now to FIG. 9, a timing diagram shows the response of a voltage generator, like that shown in FIG. 8, having six stages (e.g., N=6). FIG. 9 includes six waveforms, each of which shows a potential at a high boost node (VHI) of each stage over time. Waveforms 900, 902, 904, 906, 908 and 910 show the responses of generator stages 802-N to 802-1, respectively.

It is understood that reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A level shifting circuit, comprising:
a first driver junction field effect transistor (JFET) of a first conductivity type having a source coupled to a first supply node, a drain coupled to an output node, and a gate coupled to a first driver control node;
a first driver control circuit comprising,
a first control JFET of a second conductivity type having a source coupled to a second supply node, a gate coupled to an input node that is coupled to receive an input signal, and
a first level shifting stack that prevents a potential between the drain of the first control JFET and the first driver control node from falling below a predetermined limit; wherein
the magnitude of the potential between the first supply node and the second supply node is greater than a voltage swing of the input signal.

2. The level shifting circuit of claim 1, wherein
the first driver JFET comprises a p-channel JFET and the first supply node is a first high supply voltage node;
the first control JFET comprises an n-channel JFET and the second supply node is a low supply voltage node.

3. The level shifting circuit of claim 2, wherein:
the first driver JFET and first control JFET comprise four terminal JFETs, each having a first control gate separated from a second control gate by a channel region.

4. The level shifting circuit of claim 1, wherein:
the first level shifting stack comprises a plurality of stack JFETs of the second conductivity type having source-drain paths coupled in series, at least a first gate of each stack JFET being coupled to its source.

5. The level shifting circuit of claim 1, further including:
the first driver control circuit further includes
a disable JFET of the first conductivity type having a source coupled to the first supply node, a drain coupled to the first driver control node, and a gate coupled to a disable node;
a disable control circuit comprising,
a second control JFET of the second conductivity type having a source coupled to the second supply node, a gate coupled to the input node, and
a second level shifting stack that prevents a potential between the drain of the second control JFET and the disable node from falling below the predetermined limit.

6. The level shifting circuit of claim 1, wherein:
a second driver JFET of the second conductivity type having a source coupled to the second supply node, a drain coupled to the output node, and a gate coupled to a second driver control node; and
a low voltage control circuit that operates between voltage swing levels of the input signal, the low voltage control circuit being coupled between the input node and the second driver control node.

7. The level shifting circuit of claim 6, wherein:
the second driver control circuit couples the input node to the gate of the first control JFET.

8. A level shifting circuit, comprising:
a driver section that includes a first driver junction field effect transistor (JFET) of a first conductivity type having a source-drain path coupled between a first supply node and an output node, and a gate coupled to a first driver control node, and a second driver JFET of a second conductivity type having a source-drain path coupled between a second supply node and the output node, and a gate coupled to a second driver control node; and
a low voltage control circuit comprising a plurality of JFETs that couples an input node to the second driver control node, the low voltage control circuit being coupled between the second supply node and a third supply node; wherein
the magnitude of the potential between the first supply node and the second supply node is greater than the magnitude of the potential between the third supply node and the second supply node.

9. The level shifting circuit of claim 8, wherein:
the low voltage control circuit comprises at least one control JFET of the first conductivity type having a source coupled to the third supply node, and at least one control JFET of the second conductivity type having a source coupled to the second supply node.

10. The level shifting circuit of claim 8, further including:
the input node is coupled to receive an input signal; and
a driver enable circuit that includes an enable control device coupled in series with an enable bias stack between the first driver control node and the second supply node, the enable control device providing a low impedance path in response to the input signal having a first logic level, the enable bias stack preventing a voltage across the enable bias stack from falling below a predetermined limit.

11. The level shifting circuit of claim 10, further including:
a driver disable circuit that includes a disable control device in series with a disable bias stack coupled in series between a disable node and the second supply node, the disable control device providing a low impedance path in response to an input signal having a second logic level, the disable bias stack preventing a voltage across the disable bias stack from falling below the predetermined limit; and
a disable device that provides a low impedance path between the first driver control node and the first supply in response to the potential at the disable node.

12. The level shifting circuit of claim 11, wherein:
the enable stack and disable stack each comprise a same number of JFETs coupled to one another in series.

13. The level shifting circuit of claim 10, wherein:
the low voltage control circuit includes
a first inverting section that inverts the input signal to generate an inverse signal at a first section output, the first section output being coupled to the enable control device, and
a second inverting section that inverts the inverse signal to generate a control signal at a second section output, the second section output being coupled to the second driver control node.

14. The level shifting circuit of claim 10, further including:
an edge delay circuit coupled between the input node and the driver enable circuit, the edge delay circuit introducing a greater delay into transitions from a first signal level to a second signal level, than transitions from the second signal level to the first signal level.

15. A level shifting circuit, comprising:
a first control section coupled between a boosted power supply node and a first power supply node that includes
a first disable junction field effect transistor (JFET) of a first conductivity type having a source-drain path coupled between the boosted power supply node and a first driver control node,
a first control JFET of a second conductivity type having a source-drain path coupled to the first power supply node, and a gate coupled to receive an input signal having a voltage swing less than a difference in potential between the boosted power supply node and the first power supply node, and
a first bias circuit having first and second terminals coupled between the first driver control node and the first control JFET, respectively that ensures a minimum voltage is maintained between the first and second terminals.

16. The level shifting circuit of claim 15, wherein:
the first bias circuit comprises a plurality of JFETs coupled in series with one another.

17. The level shifting circuit of claim 15, further including:
the first disable JFET having a gate coupled to a disable node;
a second control section coupled between the boosted power supply node and the first power supply node that includes
a second disable JFET of the first conductivity type having a source-drain path coupled between the boosted power supply node and the disable node,
a second control JFET of the second conductivity type having a source-drain path coupled to the first power supply node, and
a second bias circuit having third and fourth terminals coupled between the first driver control node and the first control JFET, respectively, that that ensures a minimum voltage is maintained between the third and fourth terminals.

18. The level shifting circuit of claim 15, further including:
a driver section that includes a first driver JFET of the first conductivity type having a source drain path coupled between the boost supply node and an output node, and a gate coupled to the first driver control node.

19. The level shifting circuit of claim 18, further including:
a low voltage control section coupled between an input node and a second driver control node that outputs a low voltage control signal having the same voltage swing as the input signal; and
the driver section further includes a second driver JFET of the second conductivity type having a source-drain path coupled between the output node and the first power supply node, and a gate coupled to the second driver control node.

20. The level shifting circuit of claim 15, wherein:
the first disable JFET and a first control JFET comprise four terminal JFETs, each having a source terminal, drain terminal, first gate terminal and second gate terminal separated from the first gate terminal by a channel region.
